(19) United States
(12) Patent Application Publication
(10) Pub. No.: US 2020/0381345 A1
(43) Pub. Date: Dec. 3, 2020

(54) SEMICONDUCTOR DEVICE PACKAGE AND METHOD FOR MANUFACTURING THE SAME

(71) Applicant: Advanced Semiconductor Engineering, Inc., Kaohsiung (TW)

(72) Inventors: Yung-Shun CHANG, Kaohsiung (TW); Teck-Chong LEE, Kaohsiung (TW); Wei-Hong LAI, Kaohsiung (TW); Meng-Kai SHIH, Kaohsiung (TW)

(73) Assignee: Advanced Semiconductor Engineering, Inc., Kaohsiung (TW)

(21) Appl. No.: 16/427,197

(22) Filed: May 30, 2019

(51) Int. Cl. H01L 23/498; H01L 25/11; H01L 23/31; H01L 23/00; H01L 21/768

(52) U.S. Cl. CPC H01L 23/49811; H01L 25/115; H01L 21/76885; H01L 23/49838; H01L 24/14; H01L 23/3128

(57) ABSTRACT

A semiconductor device package includes a carrier, a conductive pillar and a first package body. The carrier has a first surface and a second surface opposite to the first surface. The conductive pillar is disposed on the second surface of the carrier. The first package is disposed on the second surface of the carrier and covers at least a portion of the conductive pillar. The conductive pillar has an uneven width.

### BACKGROUND

### 1. Technical Field

The present disclosure relates generally to a semiconductor device package and a method of manufacturing the same. More particularly, the present disclosure relates to a semiconductor device package including conductive pillars and a method of manufacturing the same.

### 2. Description of the Related Art

Conductive pillars (e.g., copper pillars) are used in a semiconductor device package for electrical connections. To protect the conductive pillars, a molding compound may be formed to cover the conductive pillars. However, during various processes to manufacture the semiconductor device package, stresses would be applied to the components or structures of the semiconductor device package to bend those components or structures (e.g., warpage) in various directions. Hence, a delamination issue may occur between the molding compound and the conductive pillars, and the conductive pillars may peel or drop off during the manufacturing processes.

### SUMMARY

In one or more embodiments, a semiconductor device package includes a carrier, a conductive pillar and a first package body. The carrier has a first surface and a second surface opposite to the first surface. The conductive pillar is disposed on the second surface of the carrier. The first package is disposed on the second surface of the carrier and covers at least a portion of the conductive pillar. The conductive pillar has an uneven width.

In one or more embodiments, a semiconductor device package includes a carrier, a conductive pillar and a first package body. The carrier has a first surface and a second surface opposite to the first surface. The conductive pillar is disposed on the second surface of the carrier. The conductive pillar has a first surface facing the carrier, a second surface opposite to the first surface and a first lateral surface extending between the first surface and the second surface of the conductive pillar. The first package is disposed on the second surface of the carrier and covers at least a portion of the conductive pillar. The first package body has a first surface facing the carrier and a second surface opposite to the first surface. The first lateral surface of the conductive pillar is not perpendicular to the first surface of the first package body.

In one or more embodiments, a method of manufacturing a semiconductor device package includes (a) providing a carrier with a seed layer disposed thereon; (b) forming a conductive pillar on the seed layer, the conductive pillar having an uneven width; and (c) forming a first package body on the seed layer to cover the conductive pillar.

### BRIEF DESCRIPTION OF THE DRAWINGS

Aspects of the present disclosure are best understood from the following detailed description when read with the accompanying drawings. It is noted that various features may not be drawn to scale, and the dimensions of the various features may be arbitrarily increased or reduced for clarity of discussion.

FIG. 1 illustrates a cross-sectional view of a semiconductor device package in accordance with some embodiments of the present disclosure;

FIG. 2A illustrates a cross-sectional view of a conductive pillar in accordance with some embodiments of the present disclosure;

FIG. 2B illustrates a cross-sectional view of a conductive pillar in accordance with some embodiments of the present disclosure;

FIG. 2C illustrates a cross-sectional view of a conductive pillar in accordance with some embodiments of the present disclosure;

FIG. 2C′ illustrates a cross-sectional view of a conductive pillar in accordance with some embodiments of the present disclosure;

FIG. 2D illustrates a cross-sectional view of a conductive pillar in accordance with some embodiments of the present disclosure;

FIG. 2E illustrates a cross-sectional view of a conductive pillar in accordance with some embodiments of the present disclosure;

FIG. 3A, FIG. 3B, FIG. 3C, FIG. 3D, FIG. 3E, FIG. 3F, FIG. 3G and FIG. 3H illustrate various stages of a method of manufacturing an electronic component in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

Structures, manufacturing and use of the embodiments of the present disclosure are discussed in detail below. It should be appreciated, however, that the embodiments set forth many applicable concepts that can be embodied in a wide variety of specific contexts. It is to be understood that the following disclosure provides many different embodiments or examples of implementing different features of various embodiments. Specific examples of components and arrangements are described below for purposes of discussion. These are, of course, merely examples and are not intended to be limiting.

Embodiments, or examples, illustrated in the drawings are disclosed below using specific language. It will nevertheless be understood that the embodiments or examples are not intended to be limiting. Any alterations and modifications of the disclosed embodiments, and any further applications of the principles disclosed in this document, as would normally occur to one of ordinary skill in the pertinent art, fall within the scope of this disclosure.

In addition, the present disclosure may repeat reference numerals and/or letters in the various examples. This repetition is for the purpose of simplicity and clarity and does not in itself dictate a relationship between the various embodiments and/or configurations discussed.

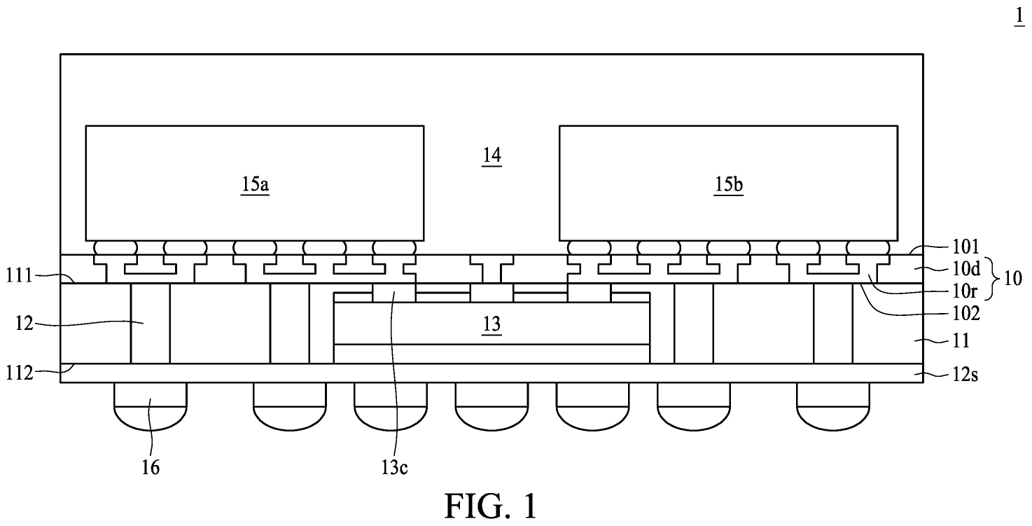

FIG. 1 illustrates a cross-sectional view of a semiconductor device package 1 in accordance with some embodiments of the present disclosure. The semiconductor device package 1 includes a circuit layer 10, package bodies 11, 14, one or more conductive pillars 12, electronic components 13, 15a, 15b and electrical contacts.

The circuit layer 10 (also can be a carrier or a substrate) includes an interconnection layer (e.g., redistribution layer, RDL) 10r and a dielectric layer 10d. A portion of the interconnection layer 10r is covered or encapsulated by the dielectric layer 10d while another portion of the interconnection layer 10r is exposed from the dielectric layer 10d to provide electrical connections for the electronic components 13, 15a and 15b. In some embodiments, the dielectric layer 10d may include molding compounds, pre-impregnated composite fibers (e.g., pre-preg), Borophosphosilicate Glass (BPSG), silicon oxide, silicon nitride, silicon oxynitride, Undoped Silicate Glass (USG), any combination of two or more thereof, or the like. Examples of molding compounds may include, but are not limited to, an epoxy resin including fillers dispersed therein. Examples of a pre-preg may include, but are not limited to, a multi-layer structure formed by stacking or laminating a number of pre-impregnated materials/sheets. In some embodiments, there may be any number of interconnection layers 10r depending on design specifications. The circuit layer 10 includes a surface 101 and a surface 102 opposite to the surface 101.

The electronic component 13 is disposed on the surface 102 of the circuit layer 10. The electronic component 13 has an active surface facing the circuit layer 10 and a back surface (also referred to as backside) opposite to the active surface. One or more electrical contacts 13c are disposed on the active surface of the electronic component 13. The electrical contacts 13c are electrically connected to the circuit layer 10 (e.g., to the interconnection layer 10r). The electronic component 13 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof.

The conductive pillars 12 are disposed on the surface 102 of the circuit layer 10 and electrically connected to the circuit layer 10 (e.g., to the interconnection layer 10r). In some embodiments, the conductive pillars 12 may include copper. However, other conductive materials such as nickel and/or aluminum or a combination of various metals or other conductive materials may also be used in the conductive pillars 12.

The package body 11 is disposed on the surface 102 of the circuit layer 10 to cover or encapsulate the electronic component 13 and the conductive pillars 12. For example, the package body 11 may cover a lateral surface of the conductive pillars 12 and expose an upper portion and a lower portion of the conductive pillar 12 for electrical connections. In some embodiments, the package body 11 includes an epoxy resin having fillers, a molding compound (e.g., an epoxy molding compound or other molding compound), a polyimide, a phenolic compound or material, a material with a silicone dispersed therein, or a combination thereof. The package body 11 has a surface 111 facing the circuit layer 10 and a surface 112 opposite to the surface 111. In some embodiments, a seed layer 12s may be disposed on the surface 112 of the package body 12 and electrically connected to the lower portion of the conductive pillar 12 exposed from the package body 11.

The electrical contacts 16 are disposed on the surface 112 of the package body 11 and electrically connected to the conductive pillars 12 to provide electrical connections between the semiconductor device package 1 and other circuits or circuit boards. In some embodiments, the electrical contacts 16 may be or include controlled collapse chip connection (C4) bump.

The electronic components 15a and 15b are disposed on the surface 101 of the circuit layer 10. Each of the electronic components 15a and 15b has an active surface facing the circuit layer 10 and a back surface (also referred to as backside) opposite to the active surface. The electronic components 15a and 15b may be electrically connected to the circuit layer 10 (e.g., to the interconnection layer 10r) by flip-chip or wire-bond techniques. Each of the electronic components 15a and 15b may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof.

The package body 14 is disposed on the surface 101 of the circuit layer 10 to cover or encapsulate the electronic components 15a and 15b. In some embodiments, the package body 14 includes an epoxy resin having fillers, a molding compound (e.g., an epoxy molding compound or other molding compound), a polyimide, a phenolic compound or material, a material with a silicone dispersed therein, or a combination thereof. In some embodiments, the package body 14 and the package body 11 may include the same material. Alternatively, the package body 14 and the package body 11 may include different materials.

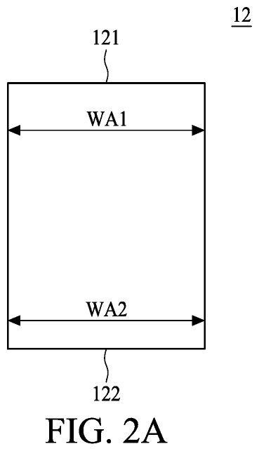

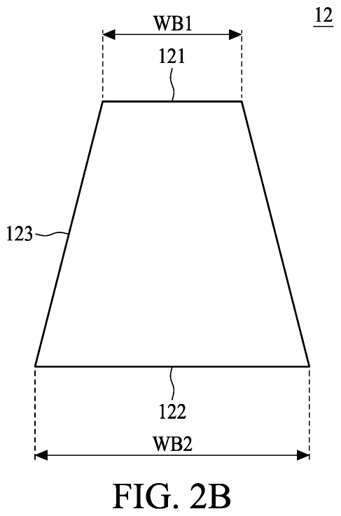

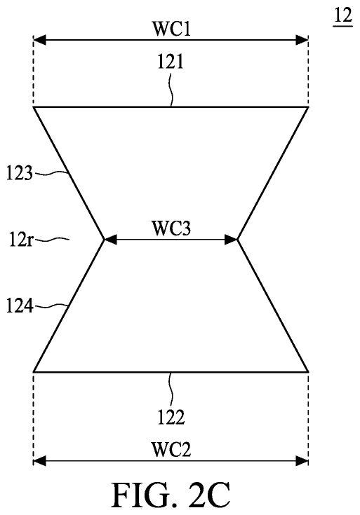

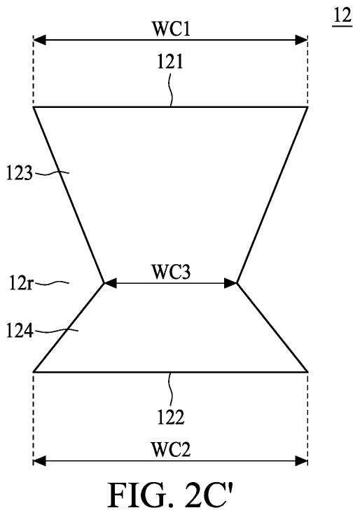

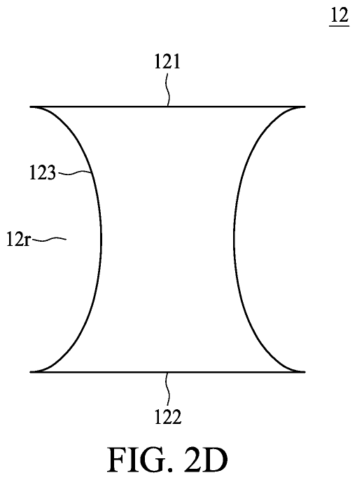

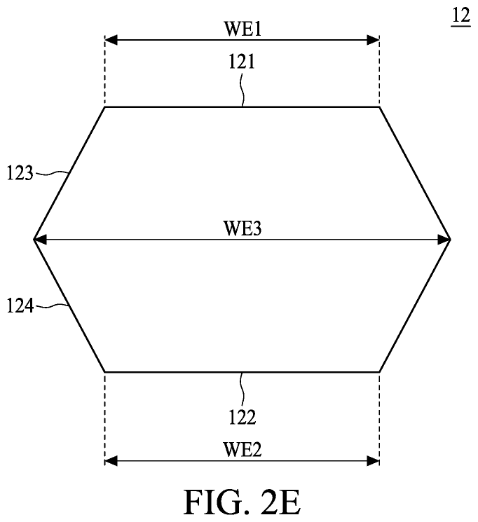

FIG. 2A illustrates a cross-sectional view of the conductive pillar 12 illustrated in FIG. 1 in accordance with some embodiments of the present disclosure. As shown in FIG. 2A, the cross-sectional view of the conductive pillar 12 is in the shape of a rectangle. For example, the conductive pillar 12 illustrated in FIG. 2A may be a cylinder. The conductive pillar 12 has a surface 121 and a surface 122 opposite to the surface 101. In some embodiments, a width WA1 of the surface 121 of the conductive pillar 12 is substantially the same as a width WA2 of the surface 122 of the conductive pillar 12.

During various processes to manufacture the semiconductor device package 1, stresses would be applied to the components or structures (e.g., the circuit layer 10, the package bodies 11, 14, the conductive pillars 12 and the like) of the semiconductor device package 1 to bend those components or structures (e.g., warpage) in various directions. Hence, a delamination issue may occur between the package body 11 and the conductive pillar 12. In accordance with the embodiments in FIG. 2A, since the conductive pillar 12 is in the shape of a cylinder, the lateral surface of the conductive pillar 12 is straight. Thus, the conductive pillar 12 may peel off or drop during the manufacturing processes, when the delamination issue occurs.

FIG. 2B illustrates a cross-sectional view of the conductive pillar 12 illustrated in FIG. 1 in accordance with some embodiments of the present disclosure. As shown in FIG. 2B, the cross-sectional view of the conductive pillar 12 is in the shape of a trapezoid. For example, a width WB1 of the surface 121 of the conductive pillar 12 is less than a width WB2 of the surface 122 of the conductive pillar 12. The conductive pillar 12 has a lateral surface 123 connected between the surface 121 and the surface 122. A slope (or gradient) of the lateral surface 123 is less than 90 degrees. In some embodiments, the surface 121 of the conductive pillar 12 faces the circuit layer 10 of the semiconductor device package 1 in FIG. 1, and the surface 122 of the conductive pillar 12 faces away from the circuit layer 10 of the semiconductor device package 1 in FIG. 1. Alternatively, the surface 121 of the conductive pillar 12 faces away from the circuit layer 10 of the semiconductor device package 1 in FIG. 1, and the surface 122 of the conductive pillar 12 faces the circuit layer 10 of the semiconductor device package 1 in FIG. 1 depending on different design specifications.

In accordance with the embodiments in FIG. 2B, since the lateral surface 123 of the conductive pillar 12 is inclined (e.g., the slope is less than 90 degrees), a contact area between the lateral surface 123 and the package body 11 of the semiconductor device package 1 in FIG. 1 is relatively large (compared with the conductive pillar 12 in FIG. 2A), which can increase the connection capability therebetween (similar to the effect of the mold lock). In addition, the stress applied to the conductive pillar 12 can be reduced during the de-carrier process (the de-carrier process will be described below). For example, the stress applied to the conductive pillar 12 in FIG. 2B is 18% less than the stress applied to the conductive pillar 12 in FIG. 2A during the de-carrier operation.

FIG. 2C illustrates a cross-sectional view of the conductive pillar 12 illustrated in FIG. 1 in accordance with some embodiments of the present disclosure. As shown in FIG. 2C, the cross-sectional view of the conductive pillar 12 is in the shape of an hourglass. For example, an upper portion of the conductive pillar 12 is sharpened from the surface 121 toward the surface 122 and a lower portion of the conductive pillar 12 is sharpened from the surface 122 toward the surface 121. The upper portion and the lower portion are connected to each other at or adjacent to the middle portion of the conductive pillar 12. For example, a lateral surface 123 is inwardly inclined from the surface 121 toward the surface 122, and a lateral surface 124 is inwardly inclined from the surface 122 toward the surface 121. The lateral surface 123 and the lateral surface 124 are connected to each other at or adjacent to the middle portion of the conductive pillar 12. For example, a width WC1 of the surface 121 of the conductive pillar 12 is substantially the same as a width WC2 of the surface 122 of the conductive pillar 12, and the width WC1 or WC2 is greater than a width WC3 of the joint portion of the lateral surface 123 and the lateral surface 124 (or the upper portion and the lower portion). In some embodiments, the conductive pillar 12 may define a recess 12r.

In accordance with the embodiments in FIG. 2C, since the lateral surface 123 and the lateral surface 124 of the conductive pillar 12 are inwardly inclined (e.g., the slope is less than 90 degrees) to define an hourglass-like conductive pillar, a contact area between the lateral surfaces 123, 124 and the package body 11 of the semiconductor device package 1 in FIG. 1 is relatively large (compared with the conductive pillar 12 in FIG. 2A), which can increase the connection capability therebetween (similar to the effect of the mold lock).

In some embodiments, as shown in FIG. 2C′, the connection portion (or joint portion) of the lateral surface 123 and the lateral surface 124 is close to the surface 122. In other embodiments, the connection portion (or joint portion) of the lateral surface 123 and the lateral surface 124 may be close to the surface 121. For example, the connection portion of the lateral surface 123 and the lateral surface 124 is not located at the middle portion of the conductive pillar 12. For example, the connection portion of the lateral surface 123 and the lateral surface 124 may be close to the surface 111 or the surface 112 of the package body 11 as shown in FIG. 1. In the case that the connection portion of the lateral surface 123 and the lateral surface 124 is close to the surface 112 of the package body 11, the effectiveness of the mold lock between the conductive pillar 12 and the package body 11 enhances, which can increase the connection capability therebetween.

FIG. 2D illustrates a cross-sectional view of the conductive pillar 12 illustrated in FIG. 1 in accordance with some embodiments of the present disclosure. The structure of the conductive pillar 12 in FIG. 2D is similar to the structure of the conductive pillar 12 in FIG. 2C, except that the conductive pillar 12 in FIG. 2D has a curved lateral surface 123. For example, the lateral surface 123 of the conductive pillar 12 in FIG. 2D defines a curved recess 12r.

FIG. 2E illustrates a cross-sectional view of the conductive pillar 12 illustrated in FIG. 1 in accordance with some embodiments of the present disclosure. As shown in FIG. 2E, the cross-sectional view of the conductive pillar 12 is in the shape of a hexagon. For example, a lateral surface 123 is outwardly inclined from the surface 121 toward the surface 122, and a lateral surface 124 is outwardly inclined from the surface 122 toward the surface 121. The lateral surface 123 and the lateral surface 124 are connected to each other at or adjacent to the middle portion of the conductive pillar 12. For example, a width WE1 of the surface 121 of the conductive pillar 12 is substantially the same as a width WE2 of the surface 122 of the conductive pillar 12, and the width WE1 or WE2 is greater than a width WE3 of the joint portion of the lateral surface 123 and the lateral surface 124. In some embodiments, the width WE3 is 20% to 50% greater than the width WE1 or WE2.

In accordance with the embodiments in FIG. 2E, since the lateral surface 123 and the lateral surface 124 of the conductive pillar 12 are outwardly inclined, a contact area between the lateral surfaces 123, 124 and the package body 11 of the semiconductor device package 1 in FIG. 1 is relatively large (compared with the conductive pillar 12 in FIG. 2A), which can increase the connection capability therebetween (similar to the effect of the mold lock). In addition, the stress applied to the conductive pillar 12 can be reduced during the de-carrier process (the de-carrier process will be described below) and the processes for forming the package body 11. For example, the stress applied to the conductive pillar 12 in FIG. 2E is 1.5% less than the stress applied to the conductive pillar 12 in FIG. 2A during the de-carrier operation, and the stress applied to the conductive pillar 12 in FIG. 2E is 8% less than the stress applied to the conductive pillar 12 in FIG. 2A during the processes for forming the package body 11.

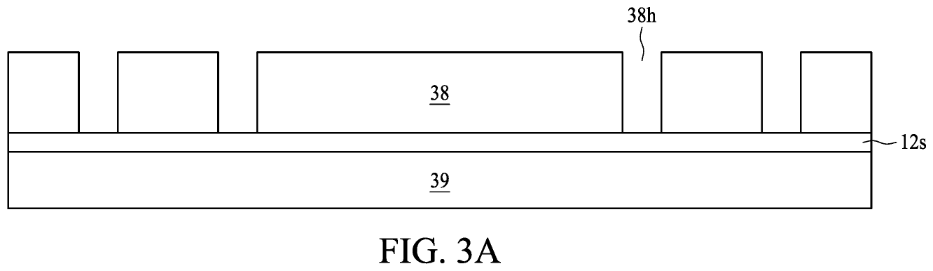

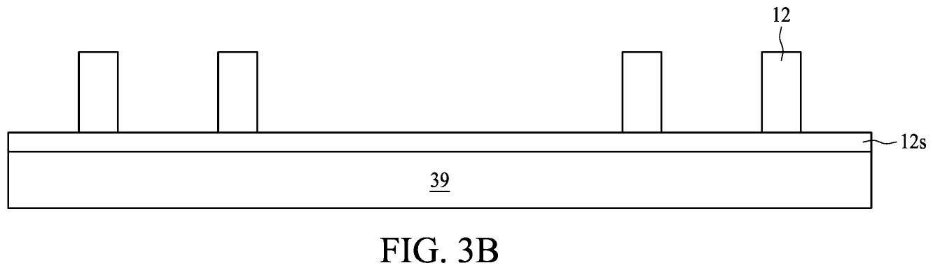

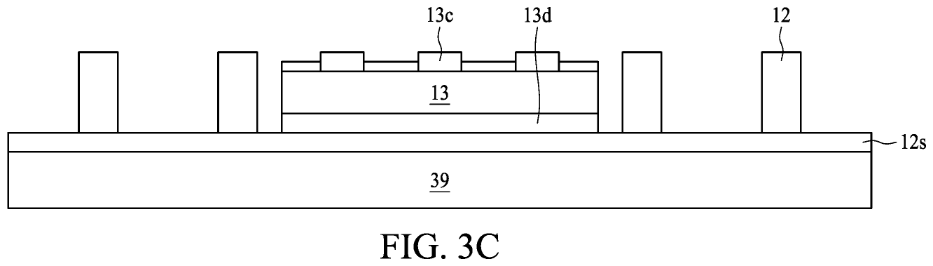

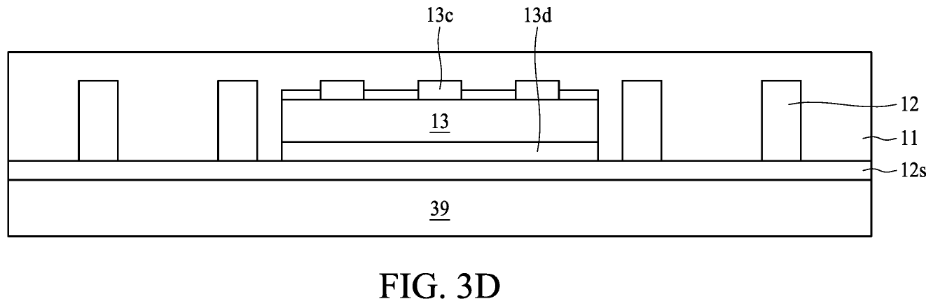

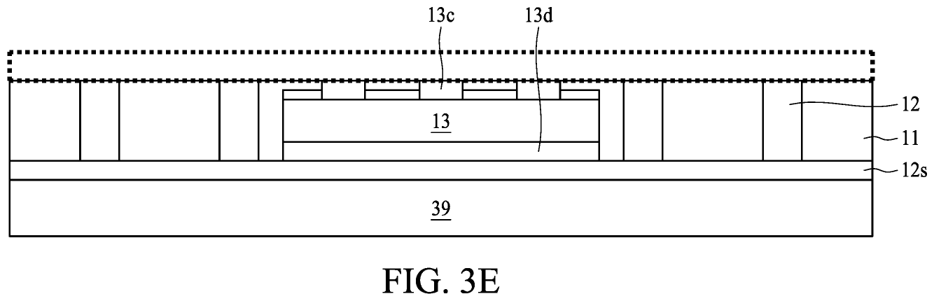

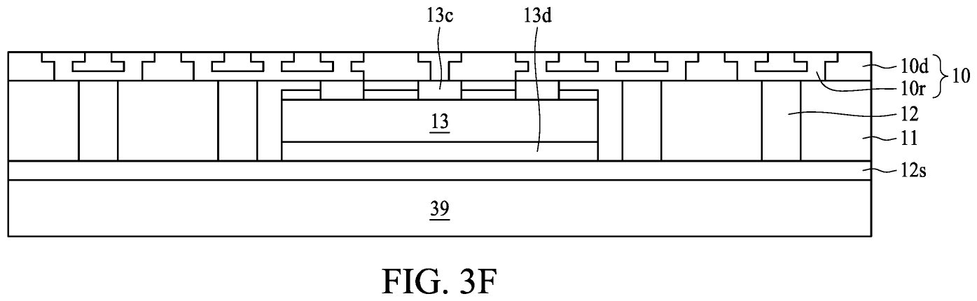

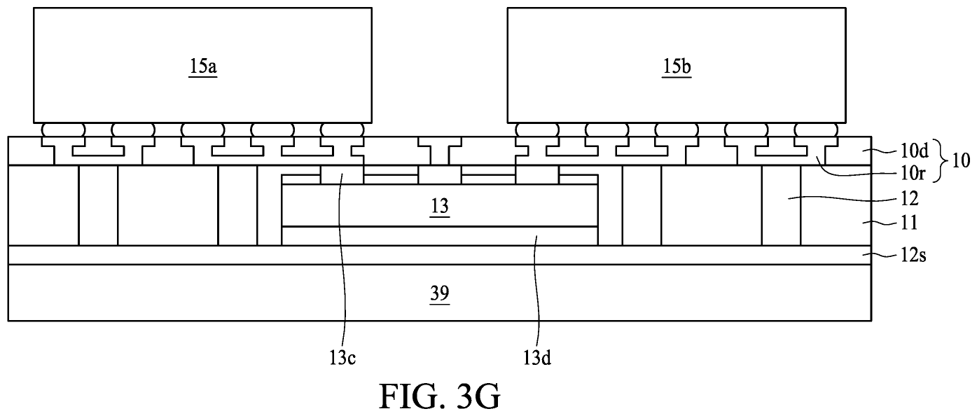

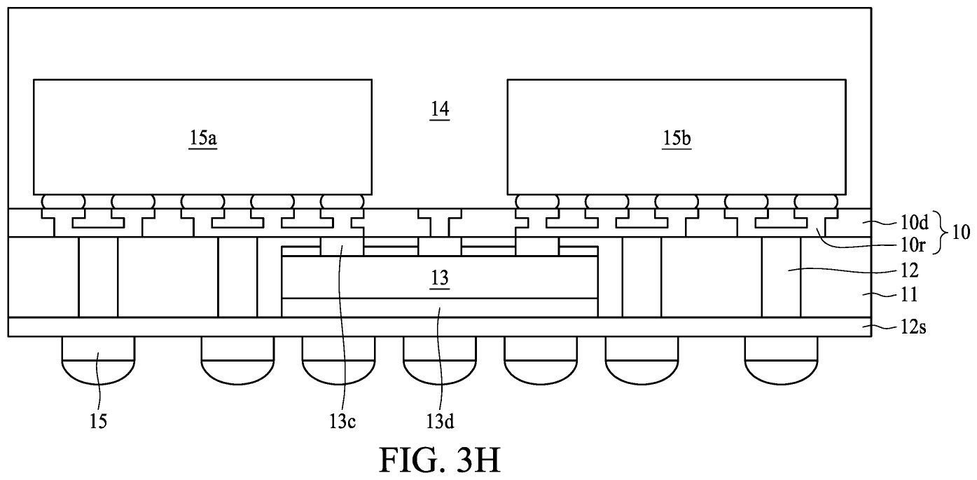

FIG. 3A, FIG. 3B, FIG. 3C, FIG. 3D, FIG. 3E, FIG. 3F and FIG. 3G are cross-sectional views of a semiconductor structure fabricated at various stages, in accordance with some embodiments of the present disclosure. Various drawings have been simplified for a better understanding of the aspects of the present disclosure. In some embodiments, the operations illustrated in FIG. 3A, FIG. 3B, FIG. 3C, FIG. 3D, FIG. 3E, FIG. 3F and FIG. 3G can be used to manufacture the semiconductor device package in FIG. 1.

Referring to FIG. 3A, a carrier 39 is provided. A seed layer 12s is disposed on the carrier 39. A photoresist 38 is disposed on the seed layer 39. The photoresist 38 has a plurality of openings 38h to expose the seed layer 39. In some embodiments, the photoresist 38 is a positive resist. Alternatively, the photoresist 38 may be a negative resist depending on different design specifications. In some embodiments, the photoresist 38 is patterned, so that the openings 38h of the photoresist 38 can be in the shape of the conductive pillar 12 as shown in any of FIGS. 2A-2E. In some embodiments, the pattern of the photoresist 38 can be controlled or determined by adjusting the parameters of lithographic processes.

Referring to FIG. 3B, a conductive material is disposed or formed within the openings 38h to form the conductive pillars 12. In some embodiments, the conductive material may be formed by, for example, plating or any other suitable processes. The photoresist 38 is then removed by, for example, etching or any other suitable processes.

Referring to FIG. 3C, the electronic component 13 is disposed on the seed layer 12s. In some embodiments, the back surface of the electronic component 13 is attached to the seed layer 12s through, for example, an adhesion layer 13d (e.g., die attach film, DAF).

Referring to FIG. 3D, the package body 11 is formed on the seed layer 12s to fully cover the electronic component 13 and the conductive pillars 12. In some embodiments, the package body 11 can be formed by molding process (e.g., compression molding, transfer molding or the like) or any other suitable processes.

Referring to FIG. 3E, a portion of the package body 11 is removed to expose an upper portion of the conductive pillars 12 and the electrical contacts 13c of the electronic component 13. In some embodiments, the portion of the package body 11 is removed by, for example, grinding or any other suitable processes.

Referring to FIG. 3F, a circuit layer 10 (including the interconnection layer 10r and the dielectric layer 10d covering a portion of the interconnection layer 10r) is formed on the package body 11 and electrically connected to the conducive pillars 12 and the electrical contacts 13c of the electronic component 13. In some embodiments, one or more micro pads (μpads) may be built on the circuit layer 10.

Referring to FIG. 3G, the electronic components 15a and 15b are disposed on the circuit layer 10 and electrically connected to the circuit layer 10 (e.g., to the interconnection layer 10r and/or to the μpads). In some embodiments, the electronic components 15a and 15b may be electrically connected to the circuit layer 10 by, for example, flip-chip or any other suitable techniques. In some embodiments, an underfill may be formed between the electronic components 15a, 15b and the circuit layer 10 to cover electrical contacts of the electronic components 15a and 15b.

Referring to FIG. 3H, the package body 14 is formed on the circuit layer 10 to cover the electronic components 15a and 15b. In some embodiments, the package body 14 can be formed by molding process (e.g., compression molding, transfer molding or the like) or any other suitable processes. The carrier 39 is removed from the seed layer 12s (e.g., de-carrier process), and then the electrical contacts 16 are disposed for formed on the seed layer 12s.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A semiconductor device package, comprising:
a carrier having a first surface and a second surface opposite to the first surface;
a conductive pillar disposed on the second surface of the carrier; and
a first package disposed on the second surface of the carrier and covering at least a portion of the conductive pillar,
wherein the conductive pillar has an uneven width.

2. The semiconductor device package of claim 1, wherein
the conductive pillar has a first surface facing the carrier and a second surface opposite to the first surface; and
a width of the first surface is less than a width of the second surface.

3. The semiconductor device package of claim 1, wherein
the conductive pillar has a first surface facing the carrier and a second surface opposite to the first surface; and
a width of the first surface is greater than a width of the second surface.

4. The semiconductor device package of claim 1, wherein
the conductive pillar has a first surface facing the carrier and a second surface opposite to the first surface;
the conductive pillar has a first portion sharpened in a direction from the first surface of the conductive pillar toward the second surface of the conductive pillar and a second portion sharpened in a direction from the second surface of the conductive pillar toward the first surface of the conductive pillar.

5. The semiconductor device package of claim 4, wherein
the first portion of the conductive pillar is connected to the second portion of the conductive pillar at or adjacent to a middle portion of the conductive pillar;
a width of the first surface of the conductive pillar is substantially the same as a width of the second surface of the conductive pillar; and
the width of the first surface or the second surface of the conductive pillar is greater than a width of a joint portion of the first portion and the second portion of the conductive pillar.

6. The semiconductor device package of claim 4, wherein the first portion of the conductive pillar is connected to the second portion of the conductive pillar, and an interface between the first portion and the second portion is closer to the first surface of the conductive pillar.

7. The semiconductor device package of claim 1, wherein
the conductive pillar has a first surface facing the carrier and a second surface opposite to the first surface;
the conductive pillar has a first lateral surface inwardly inclined from the first surface of the conductive pillar toward the second surface of the conductive pillar and a second lateral surface inwardly inclined from the second surface of the conductive pillar toward the first surface of the conductive pillar; and
the first lateral surface is connected to the second surface at or adjacent to a middle portion of the conductive pillar.

8. The semiconductor device package of claim 7, wherein the first lateral surface and the second lateral surface have curved surfaces.

9. The semiconductor device package of claim 1, wherein
the conductive pillar has a first surface facing the carrier and a second surface opposite to the first surface;
the conductive pillar has a first lateral surface outwardly inclined from the first surface of the conductive pillar toward the second surface of the conductive pillar and a second lateral surface outwardly inclined from the second surface of the conductive pillar toward the first surface of the conductive pillar; and
the first lateral surface is connected to the second lateral surface at or adjacent to a middle portion of the conductive pillar.

10. The semiconductor device package of claim 9, wherein a width of a joint portion of the first lateral surface and the second lateral surface of the conductive pillar is 20% to 50% greater than a width of the first surface or the second surface of the conductive pillar.

11. The semiconductor device package of claim 1, further comprising a first electronic component disposed on the second surface of the carrier and covered by the first package body.

12. The semiconductor device package of claim 1, further comprising:
a second electronic component disposed on the first surface of the carrier; and
a second package body disposed on the first surface of the carrier and covering the second electronic component.

13. A semiconductor device package, comprising:
a carrier having a first surface and a second surface opposite to the first surface;
a conductive pillar disposed on the second surface of the carrier, the conductive pillar having a first surface facing the carrier, a second surface opposite to the first surface and a first lateral surface extending between the first surface and the second surface of the conductive pillar; and
a first package disposed on the second surface of the carrier and covering at least a portion of the conductive pillar, the first package body having a first surface facing the carrier and a second surface opposite to the first surface,
wherein the first lateral surface of the conductive pillar is not perpendicular to the first surface of the first package body.

14. The semiconductor device package of claim 13, wherein the first lateral surface is inwardly inclined from the first surface of the conductive pillar toward the second surface of the conductive pillar.

15. The semiconductor device package of claim 13, wherein the first lateral surface is outwardly inclined from the first surface of the conductive pillar toward the second surface of the conductive pillar.

16. The semiconductor device package of claim 13, wherein the conductive pillar further includes a second lateral surface extending between the first lateral surface and the second surface of the conductive pillar, and the second lateral surface is not perpendicular to the second surface of the first package body.

17. The semiconductor device package of claim 16, wherein
the first lateral surface is inwardly inclined from the first surface of the conductive pillar toward the second surface of the conductive pillar;
the second lateral surface is inwardly inclined from the second surface of the conductive pillar toward the first surface of the conductive pillar; and
the first lateral surface and the second lateral surface are connected at or adjacent to a middle portion of the conductive pillar.

18. The semiconductor device package of claim 17, wherein the first lateral surface and the second lateral surface have curved surfaces.

19. The semiconductor device package of claim 16, wherein
the first lateral surface is inwardly inclined from the first surface of the conductive pillar toward the second surface of the conductive pillar;
the second lateral surface is inwardly inclined from the second surface of the conductive pillar toward the first surface of the conductive pillar; and
the first lateral surface and the second lateral surface are connected; and
a connection between the first lateral surface and the second lateral surface is closer to the first surface of the conductive pillar.

20. The semiconductor device package of claim 16, wherein
the first lateral surface is outwardly inclined from the first surface of the conductive pillar toward the second surface of the conductive pillar;
the second lateral surface is outwardly inclined from the second surface of the conductive pillar toward the first surface of the conductive pillar; and
the first lateral surface and the second lateral surface are connected at or adjacent to a middle portion of the conductive pillar.

21. The semiconductor device package of claim 20, wherein a width of a joint portion of the first lateral surface and the second lateral surface of the conductive pillar is 20% to 50% greater than a width of the first surface or the second surface of the conductive pillar.

22. The semiconductor device package of claim 13, further comprising a first electronic component disposed on the second surface of the carrier and covered by the first package body.

23. The semiconductor device package of claim 13, further comprising:
a second electronic component disposed on the first surface of the carrier; and
a second package body disposed on the first surface of the carrier and covering the second electronic component.

24. A method of manufacturing a semiconductor device package, comprising:
(a) providing a carrier with a seed layer disposed thereon;
(b) forming a conductive pillar on the seed layer, the conductive pillar having an uneven width; and
(c) forming a first package body on the seed layer to cover the conductive pillar.

25. The method of claim 24, wherein operation (b) further comprises:
disposing a photoresist on the seed layer, the photoresist having an opening to expose the seed layer, the opening has a sidewall not perpendicular to the seed layer; and
filling the opening with a conductive material.

26. The method of claim 25, wherein the photoresist is a positive resist.

27. The method of claim 24, wherein operation (c) further comprises:
disposing a first electronic component on the seed layer;
forming the first package body to fully cover the first electronic component and the conductive pillar; and
removing a portion of the first package body to expose electrical contacts of the first electronic component and a portion of the conductive pillar.

28. The method of claim 27, further comprising:
forming a distribution layer on the conductive pillar and the electrical contacts;
forming a dielectric layer to cover at least a portion of the distribution layer;
disposing a second electronic component on the distribution layer exposed from the dielectric layer; and
forming a second package body to cover the second electronic component.
